(19) United States
(12) Patent Application Publication
(10) Pub. No.: US 2025/0226366 A1
(43) Pub. Date: Jul. 10, 2025

(54) SEMICONDUCTOR PACKAGE

(71) Applicant: Samsung Electronics Co., Ltd., Suwon-si (KR)

(72) Inventors: Hyunsoo Chung, Suwon-si (KR); Jinchan Ahn, Suwon-si (KR)

(21) Appl. No.: 18/969,936

(22) Filed: Dec. 5, 2024

(30) Foreign Application Priority Data
Jan. 9, 2024 (KR) 10-2024-0003612

(51) Int. Cl. H01L 25/16; H01L 23/31; H01L 23/48; H01L 23/538; H10B 80/00; H10D 1/68

(52) U.S. Cl. CPC H01L 25/16; H01L 23/3135; H01L 23/481; H01L 23/5384; H10D 1/68; H10B 80/00

(57) ABSTRACT

A semiconductor package includes a logic chip, a redistribution wiring structure, memory chips and a molding member. The logic chip includes a first substrate and a passive element on a portion of the first substrate. The redistribution wiring structure is on the logic chip, and is electrically connected to the passive element. The memory chips are sequentially stacked on the redistribution wiring structure in a vertical direction. The molding member is on the logic chip, and extends on sidewalls of the redistribution wiring structure and the memory chips. The passive element does not overlap the memory chips in the vertical direction.

### CROSS-REFERENCE TO RELATED APPLICATION

This application claims priority under 35 U.S.C. § 119 to Korean Patent Application No. 10-2024-0003612, filed on Jan. 9, 2024 in the Korean Intellectual Property Office (KIPO), the contents of which are herein incorporated by reference in their entirety.

### FIELD OF THE INVENTION

Example embodiments relate to a semiconductor package. More particularly, example embodiments relate to a semiconductor package including a plurality of stacked chips.

### BACKGROUND OF THE INVENTION

A high bandwidth memory (HBM) package may include a plurality of memory chips stacked on a logic chip in a vertical direction, and the number of through electrodes in the logic chip increases and the pitch between the through electrodes decreases so that the HBM package may have a high capacity. Thus, a space for a passive element such as a capacitor in the logic chip may not be sufficient.

### SUMMARY

Example embodiments provide a semiconductor package having enhanced electrical characteristics.

According to example embodiments, there is provided a semiconductor package. The semiconductor package may include a logic chip, a redistribution wiring structure, memory chips and a molding member. The logic chip may include a first substrate and a passive element on a portion of the first substrate. The redistribution wiring structure may be on the logic chip, and may be electrically connected to the passive element. The memory chips may be sequentially stacked on the redistribution wiring structure in a vertical direction. The molding member may be on the logic chip, and may extend on sidewalls of the redistribution wiring structure and the memory chips. The passive element may not overlap the memory chips in the vertical direction.

According to example embodiments, there is provided a semiconductor package. The semiconductor package may include a logic die, a redistribution wiring structure, memory dies and a molding member. The logic die may include a substrate, a through electrode structure, a protective pattern structure and a capacitor. The substrate may include first and second surfaces opposite to each other in a vertical direction. The through electrode structure may extend through the substrate, and may include a protrusion portion protruding beyond the second surface of the substrate. The protective pattern structure may be on the second surface of the substrate, and may extend on a sidewall of the protrusion portion of the through electrode structure. A lower portion of the capacitor may extend into a portion of the substrate adjacent to the second surface thereof, and an upper portion of the capacitor may have the protective pattern structure thereon. The redistribution wiring structure may be on the logic die, and may be electrically connected to the capacitor. The memory dies may be sequentially stacked on the redistribution wiring structure. The molding member may be on the logic die, and may extend on sidewalls of the redistribution wiring structure and the memory dies. Each of the memory dies may not overlap the capacitor in the vertical direction.

According to example embodiments, there is provided a semiconductor package. The semiconductor package may include a buffer die, a redistribution wiring structure, core dies, an adhesion layer and a molding member. The buffer die may include a first substrate, a logic device, a first wiring structure, a first through electrode structure, a first protective pattern structure and a capacitor. The first substrate may include first and second surfaces opposite to each other in a vertical direction. The logic device may be provided in the first substrate. The first wiring structure may be electrically connected to the logic device. The first through electrode structure may extend through the first substrate in the vertical direction, and may include a first protrusion portion protruding beyond the second surface of the first substrate. The first protective pattern structure may be on the second surface of the first substrate, and may extend on a sidewall of the first protrusion portion of the first through electrode structure. A lower portion of the capacitor may extend into a portion of the first substrate adjacent to the second surface thereof, and an upper portion of the capacitor may have the first protective pattern structure thereon. The redistribution wiring structure may be disposed on the buffer die, and may be electrically connected to the capacitor. The core dies may be sequentially stacked on the redistribution wiring structure in the vertical direction. Adhesion layers may be provided between the redistribution wiring structure and a lowermost one of the core dies, and between respective ones of the core dies that are sequentially stacked. The molding member may be on the buffer die, and may extend on sidewalls of the redistribution wiring structure, the core dies, and the adhesion layers. The capacitor may not overlap the core dies in the vertical direction.

The semiconductor package in accordance with example embodiments may have sufficient passive elements even without an additional space for the passive elements, and thus the semiconductor package may have enhanced electrical characteristics and an enhanced integration degree.

### BRIEF DESCRIPTION OF THE DRAWINGS

FIG. 1 is a cross-sectional view illustrating a semiconductor package in accordance with example embodiments.

FIGS. 2, 3, 4, 5, 6, 7, 8, 9, 10 and 11 are cross-sectional views illustrating a method of manufacturing a semiconductor package in accordance with example embodiments.

FIG. 12 is a cross-sectional view illustrating a semiconductor package in accordance with example embodiments.

FIG. 13 is a cross-sectional view illustrating an electronic device in accordance with example embodiments.

### DETAILED DESCRIPTION OF EXAMPLE EMBODIMENTS

The above and other aspects and features of the semiconductor package and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

Hereinafter, a direction substantially perpendicular to an upper surface of a substrate may be referred to as a vertical direction, and a direction substantially parallel to the upper surface of the substrate may be referred to as a horizontal direction. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

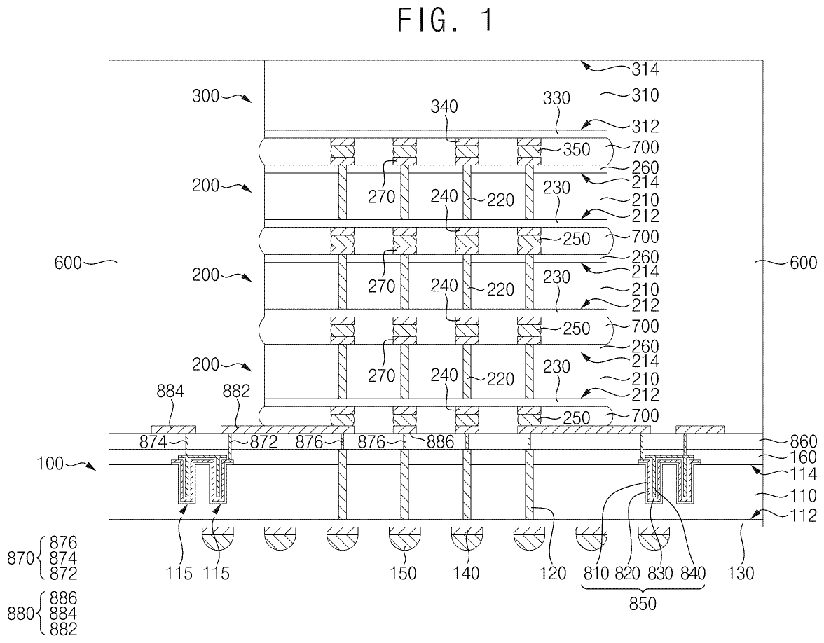

FIG. 1 is a cross-sectional view illustrating a semiconductor package in accordance with example embodiments.

Referring to FIG. 1, the semiconductor package may include a first semiconductor chip 100, a first redistribution layer (RDL) 860 and a redistribution wiring structure 880 on the first semiconductor chip 100, a plurality of second semiconductor chips 200 stacked on the first RDL 860 and the redistribution wiring structure 880, a third semiconductor chip 300 on an uppermost one of the second semiconductor chips 200, an adhesion layer 700 between the first RDL 860 and the redistribution wiring structure and the second semiconductor chip 200, between the second semiconductor chips 200 and between the uppermost one of the second semiconductor chips 200 and the third semiconductor chip 300, and a molding member 600 on the first semiconductor chip 100 and covering the first RDL 860, the redistribution wiring structure 880 and the second and third semiconductor chips 200 and 300.

FIG. 1 shows that the semiconductor package includes three second semiconductor chips 200 between the first RDL 860 and the redistribution wiring structure 880 and the third semiconductor chip 300, however, the inventive concept may not be limited thereto, and may include more than three second semiconductor chips 200. In example embodiments, the semiconductor package may be a high bandwidth memory (HBM) package.

In example embodiments, the first semiconductor chip 100 may be a buffer die, and may include a logic device, e.g., a controller. Each of the second and third semiconductor chips 200 and 300 may be a core die, and may include a volatile memory device, e.g., DRAM device, SRAM device, etc., or a non-volatile memory device, e.g., flash memory device, EEPROM device, etc. Each of the second semiconductor chips 200 may be a middle core die, and the third semiconductor chip 300 may be a top core die.

The first semiconductor chip 100 may also be referred to as a logic chip or logic die, and each of the second and third semiconductor chips 200 and 300 may also be referred to as a memory chip or a memory die.

The first semiconductor chip 100 may include a first substrate 110 having first and second surfaces 112 and 114 opposite to each other in the vertical direction, a first through electrode structure 120 extending through the first substrate 110, a first insulating interlayer and a second insulating interlayer 130 sequentially stacked in the vertical direction beneath the first surface 112 of the first substrate 110, a first conductive pad 140 beneath the second insulating interlayer 130, a first conductive connection member 150 beneath the first conductive pad 140, and a first protective pattern structure 160 on the second surface 114 of the first substrate 110.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A circuit device, e.g., a logic device may be disposed beneath the first surface 112 of the first substrate 110. The circuit device may include circuit patterns, which may be covered by the first insulating interlayer. The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

The second insulating interlayer 130 may contain a first wiring structure therein. The first wiring structure may include, e.g., wirings, vias, contact plugs, etc.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The first conductive pad 140 may be disposed under the second insulating interlayer 130, and may contact the first wiring structure to be electrically connected thereto. In example embodiments, a plurality of first conductive pads 140 may be spaced apart from each other in the horizontal direction.

In example embodiments, the first conductive pad 140 may include a first seed pattern and a first conductive pattern sequentially stacked in the vertical direction downwardly from the second insulating interlayer. The first seed pattern may include, e.g., titanium, and the first conductive pattern may include, e.g., nickel, copper, gold, etc.

The first conductive connection member 150 may contact a lower surface of the first conductive pad 140. The first conductive connection member 150 may be, e.g., a conductive bump. The first conductive connection member 150 may include a metal, e.g., tin, or a tin alloy including, e.g., tin/silver, tin/copper, tin/indium, tin/silver/copper, etc.

The first through electrode structure 120 may extend through the first substrate 110 in the vertical direction. A protrusion portion of the first through electrode structure 120 may protrude upwardly (i.e., beyond the second surface 114 of the first substrate 110) in the vertical direction, and may be covered by the first protective pattern structure 160. A plurality of first through electrode structures 120 may be spaced apart from each other in the horizontal direction. In example embodiments, the first through electrode structure 120 may include a first through electrode extending in the vertical direction, a first barrier pattern covering a sidewall of the first through electrode, and a first insulation pattern covering an outer sidewall of the first barrier pattern.

The first through electrode may include a metal, e.g., copper, aluminum, etc., the first barrier pattern may include a metal nitride, e.g., titanium nitride, tantalum nitride, etc., and the first insulation pattern may include an oxide, e.g., silicon oxide or an insulating nitride, e.g., silicon nitride.

In an example embodiment, the first through electrode structure 120 may extend through the first protective pattern structure 160, the first substrate 110 and the first insulating interlayer to contact the first wiring structure, and may be electrically connected to the first conductive pad 140 by the first wiring structure.

Alternatively, the first through electrode structure 120 may extend through the first protective pattern structure 160, the first substrate 110 and the first insulating interlayer and the second insulating interlayer 130 to contact the first conductive pad 140, and may be electrically connected thereto. Alternatively, the first through electrode structure 120 may extend through the first protective pattern structure 160 and the first substrate 110 to contact one of the circuit patterns included in the circuit device covered by the first insulating interlayer, and may be electrically connected to the first conductive pad 140 by the one of the first circuit patterns and the first wiring structure.

The first protective pattern structure 160 may be disposed on the second surface 114 of the first substrate 110, and may surround an upper portion of the first through electrode structure 120.

In example embodiments, the first protective pattern structure 160 may include a first protective pattern and a second protective pattern sequentially stacked in the vertical direction on the second surface 114 of the first substrate 110. A portion of the first protective pattern adjacent to the first through electrode structure 120 may protrude upwardly in the vertical direction, and an upper surface of the portion of the first protective pattern may be substantially coplanar with an upper surface of the first through electrode structure 120. An outer sidewall of the portion of the first protective pattern may be covered by the second protective pattern.

The first protective pattern may include an oxide, e.g., silicon oxide, and the second protective pattern may include an insulating nitride, e.g., silicon nitride.

A passive element may be disposed at an upper portion of the first semiconductor chip 100, e.g., at a portion adjacent to the second surface 114 of the first semiconductor chip 100. In example embodiments, the passive element may not overlap the second and third semiconductor chips 200 and 300 in the vertical direction. Components or layers described with reference to “overlap” in a particular direction may be at least partially obstructed by one another when viewed along a line extending in the particular direction or in a plane perpendicular to the particular direction. The passive element may include, e.g., a capacitor, an inductor, a resistor, etc. Hereinafter, the capacitor 850 as the passive element is described.

In example embodiments, a lower portion of the capacitor 850 may extend through a portion of the first semiconductor chip 100 adjacent to the second surface 114, and an upper portion of the capacitor 850 may protrude upwardly over the second surface 114 to be covered by the first protective pattern structure 160.

In example embodiments, the capacitor 850 may include a lower electrode 820, a dielectric pattern 830 and an upper electrode 840 sequentially stacked in the vertical direction, and a lower surface of the lower electrode 820 may be covered by a pad 810. In an example embodiment, the pad 810, the lower electrode 820 and the dielectric pattern 830 may be conformally stacked on an inner wall of a trench 115, which may be disposed on a portion of the first semiconductor chip 100 adjacent to the second surface 114, and the second surface 114 of the first semiconductor chip 100, and the upper electrode 840 may be disposed on the dielectric pattern 830 to fill a remaining portion of the trench 115.

In example embodiments, a portion of an upper surface of the lower electrode 820 may not be covered by the dielectric pattern 830 and the upper electrode 840, but may be at least partially exposed thereby. The term “exposed” may be used to describe relationships between elements and/or certain intermediate processes in fabricating a completed semiconductor device, but may not necessarily require exposure of the particular region, layer, structure or other element in the context of the completed device.

The pad 810 may include an oxide, e.g., silicon oxide, each of the lower and upper electrodes 820 and 840 may include, e.g., a metal, a metal nitride, a metal silicide, doped polysilicon, and the dielectric pattern 830 may include a metal oxide having a high dielectric constant, e.g., hafnium oxide, zirconium oxide, etc.

The first RDL 860 may be disposed on the first protective pattern structure 160 and the first through electrode structure 120, and the redistribution wiring structure 880 may be disposed on the first RDL 860. The redistribution wiring structure 880 may include first to third redistribution wirings 882, 884 and 886.

In example embodiments, a via structure 870 may extend through the first protective pattern structure 160 and the first RDL 860. The via structure 870 may include first to third vias 872, 874 and 876.

The first via 872 may contact an upper surface of the lower electrode 820 of the capacitor 850 and a lower surface of the first redistribution wiring 882 of the redistribution wiring structure 880, the second via 874 may contact an upper surface of the upper electrode 840 of the capacitor 850 and a lower surface of the second redistribution wiring 884 of the redistribution wiring structure 880, and the third via 876 may contact an upper surface of the first through electrode structure 120 and a lower surface of the third redistribution wiring 886 of the redistribution wiring structure 880.

In example embodiments, a plurality of third vias 876 may be spaced apart from each other in the horizontal direction, which may correspond to the plurality of first through electrode structures 120 spaced apart from each other in the horizontal direction. Some of the plurality of third vias 876 may contact the upper surface of the first through electrode structure 120 and the lower surface of the first redistribution wiring 882 of the redistribution wiring structure 880.

That is, the first redistribution wiring 882 may commonly contact upper surfaces of the first and third vias 872 and 876, the second redistribution wiring 884 may contact an upper surface of the second via 874, and the third redistribution wiring 886 may contact an upper surface of the third via 876. Thus, the lower electrode 820 of the capacitor 850 may be electrically connected to the first through electrode structure 120 by the first via 872, the first redistribution wiring 882 and the third via 876, and the upper electrode 840 of the capacitor 850 may be electrically connected to the second redistribution wiring 884 by the second via 874.

However, the inventive concept may not be limited thereto, and in some embodiments, the upper electrode 840 of the capacitor 850 may be electrically connected to the first through electrode structure 120 by the first via 872, the first redistribution wiring 882 and the third via 876, and the lower electrode 820 of the capacitor 850 may be electrically connected to the second redistribution wiring 884 by the second via 874.

Some of the first and second redistribution wirings 882 and 884 included in the redistribution wiring structure 880 and the third redistribution wiring 886 may serve as a second conductive pad.

FIG. 1 shows that the first RDL 860 has single layer and the redistribution wiring structure 880 has a single layer, however, the inventive concept may not be limited thereto, and in some embodiments, the first RDL 860 may have a plurality of layers sequentially stacked in the vertical direction, and the redistribution wiring structure 880 may have a plurality of layers sequentially stacked in the vertical direction. In this case, the vias may also be disposed at a plurality of levels, respectively. The term “level” as used herein may refer to a distance or spacing from a reference element or layer as described herein, for example, relative to the first chip 100 in the stack.

In an example embodiment, the first RDL 860 may include an organic insulating material. Alternatively, the first RDL 860 may include an inorganic insulating material, e.g., silicon oxide, silicon nitride, etc.

Each of the first to third vias 872, 874 and 876 and the first to third redistribution wirings 882, 884 and 886 may include a conductive material, e.g., a metal, a metal nitride, a metal silicide, etc.

Each of the second semiconductor chips 200 may include a second substrate 210 having first and second surfaces 212 and 214 opposite to each other in the vertical direction, a second through electrode structure 220 extending through the second substrate 210, a third insulating interlayer and a fourth insulating interlayer 230 sequentially stacked in the vertical direction beneath the first surface 212 of the second substrate 210, a third conductive pad 240 beneath the fourth insulating interlayer 230, a second protective pattern structure 260 on the second surface 214 of the second substrate 210, and a fourth conductive pad 270 on the second protective pattern structure 260 and contacting an upper surface of the second through electrode structure 220.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be disposed on or beneath the first surface 212 of the second substrate 210. The circuit device may include circuit patterns, which may be covered by the third insulating interlayer.

The fourth insulating interlayer 230 may contain a second wiring structure therein. The second wiring structure may include, e.g., wirings, vias, contact plugs, etc.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The third conductive pad 240 may be disposed under the fourth insulating interlayer 230, and may contact the second wiring structure to be electrically connected thereto. In example embodiments, a plurality of third conductive pads 240 may be spaced apart from each other in the horizontal direction.

In example embodiments, the third conductive pad 240 may include a second seed pattern and a second conductive patterns sequentially stacked downwardly in the vertical direction from the fourth insulating interlayer 230. The second seed pattern may include, e.g., titanium, and the second conductive pattern may include, e.g., nickel and gold.

The second through electrode structure 220 may extend through the second substrate 210 in the vertical direction. A protrusion portion of the second through electrode structure 220 may protrude upwardly in the vertical direction (i.e., beyond the second surface 214 of the second substrate 210), and may be covered by the second protective pattern structure 260. A plurality of second through electrode structures 220 may be spaced apart from each other in the horizontal direction. In example embodiments, the second through electrode structure 220 may include a second through electrode extending in the vertical direction, a second barrier pattern covering a sidewall of the second through electrode, and a second insulation pattern covering an outer sidewall of the second barrier pattern.

The second through electrode may include a metal, e.g., copper, aluminum, etc., the second barrier pattern may include a metal nitride, e.g., titanium nitride, tantalum nitride, etc., and the second insulation pattern may include an oxide, e.g., silicon oxide or an insulating nitride, e.g., silicon nitride.

In an example embodiment, the second through electrode structure 220 may extend through the second protective pattern structure 260, the second substrate 210 and the third insulating interlayer to contact the second wiring structure, and may be electrically connected to the third conductive pad 240 by the second wiring structure.

Alternatively, the second through electrode structure 220 may extend through the second protective pattern structure 260, the second substrate 210 and the third insulating interlayer and the fourth insulating interlayer 230 to contact the third conductive pad 240, and may be electrically connected thereto. Alternatively, the second through electrode structure 220 may extend through the second protective pattern structure 260 and the second substrate 210 to contact one of the circuit patterns included in the circuit device covered by the third insulating interlayer, and may be electrically connected to the third conductive pad 240 by one of the circuit patterns and the second wiring structure.

The second protective pattern structure 260 may be disposed on the second surface 214 of the second substrate 210, and may surround an upper portion of the second through electrode structure 220. In example embodiments, the second protective pattern structure 260 may include a third protective pattern and a fourth protective pattern sequentially stacked in the vertical direction on the second surface 214 of the second substrate 210. A portion of the third protective pattern adjacent to the second through electrode structure 220 may protrude upwardly in the vertical direction, and an upper surface of the portion of the second protective pattern structure 260 may be substantially coplanar with an upper surface of the second through electrode structure 220. An outer sidewall of the portion of the third protective pattern may be covered by the fourth protective pattern.

The third protective pattern may include an oxide, e.g., silicon oxide, and the fourth protective pattern may include an insulating nitride, e.g., silicon nitride.

The fourth conductive pad 270 may be electrically connected to the third conductive pad 240 by the second through electrode structure 220 and the second wiring structure. In example embodiments, a plurality of fourth conductive pads 270 may be spaced apart from each other in the horizontal direction.

In example embodiments, the fourth conductive pad 270 may include a third seed pattern and a third conductive pattern sequentially stacked upwardly in the vertical direction from the second protective pattern structure 260. The third seed pattern may include, e.g., titanium, and the third conductive pattern may include, e.g., nickel, copper, gold, etc.

In example embodiments, the second conductive connection member 250 included in a lowermost one of the second semiconductor chips 200 may contact a lower surface of the third conductive pad 240 and an upper surface of the second conductive pad included in the redistribution wiring structure 880, and the second conductive connection member 250 included in other ones of the second semiconductor chips 200 may contact lower and upper surfaces of the third and fourth conductive pads 240 and 270, respectively.

The second conductive connection member 250 may be, e.g., a conductive bump. The second conductive connection member 250 may include a metal, e.g., tin, or solder.

The adhesion layer 700 be disposed between the second semiconductor chip 200 and the first RDL 860 and the redistribution wiring structure 880, and may bond the second semiconductor chip 200 and the first RDL 860 and the redistribution wiring structure 880 with each other. The adhesion layer 700 may surround a structure including the second conductive pad, the third conductive pad 240 and the second conductive connection member 250, or a structure including the third and fourth conductive pads 240 and 270 and the second conductive connection member 250. The adhesion layer 700 may include a non-conductive film (NCF), e.g., thermosetting resin.

The third semiconductor chip 300 may be stacked on the second semiconductor chip 200, and the adhesion layer 700 may be disposed therebetween.

The third semiconductor chip may have a structure substantially the same as or similar to that of the second semiconductor chip 200, and thus repeated explanations of common or similar elements are omitted herein.

The third semiconductor chip 300 may include a third substrate 310 having first and second surfaces 312 and 314 opposite to each other in the vertical direction, a fifth insulating interlayer and a sixth insulating interlayer 330 sequentially stacked in the vertical direction beneath the first surface 312 of the third substrate 310, a fifth conductive pad 340 beneath the sixth insulating interlayer 330 and a third conductive connection member 350.

A circuit device, e.g., a memory device may be disposed on or beneath the first surface 312 of the third substrate 310. The circuit device may include circuit patterns, which may be covered by the fifth insulating interlayer. The sixth insulating interlayer 330 may contain a third wiring structure therein.

The fifth conductive pad 340 may be disposed under the sixth insulating interlayer 330, and may contact the third wiring structure to be electrically connected thereto. In example embodiments, a plurality of fifth conductive pads 340 may be spaced apart from each other in the horizontal direction.

In example embodiments, the fifth conductive pad 340 may include a fourth seed pattern and a fourth conductive pattern sequentially stacked downwardly in the vertical direction from the sixth insulating interlayer 330. The fourth seed pattern may include, e.g., titanium, and the fourth conductive pattern may include, e.g., nickel, copper, gold, etc.

The third conductive connection member 350 contact upper and lower surfaces of the fourth and fifth conductive pads 270 and 340, respectively.

The adhesion layer 700 may be disposed between an uppermost one of the second semiconductor chips 200 and the third semiconductor chip 300, and may bond the uppermost one of the second semiconductor chips 200 and the third semiconductor chip 300 with each other. The adhesion layer 700 may surround the fourth and fifth conductive pads 270 and 340 and the third conductive connection member 350.

The molding member 600 may cover sidewalls of the second and third semiconductor chips 200 and 300 on the first RDL 860 and the redistribution wiring structure 880, and an upper surface of the molding member 600 may be substantially coplanar with an upper surface of the third semiconductor chip 300. The molding member 600 may include a polymer, e.g., epoxy molding compound (EMC).

In the semiconductor package, one or more passive elements such as the capacitor 850 may be disposed at a portion of the first semiconductor chip 100 adjacent to the second surface 114 of the first substrate 110, and may not overlap the second and third semiconductor chips 200 and 300 in the vertical direction.

That is, for example, if the first through electrode structures 120, which may be disposed in the first substrate 110 of the first semiconductor chip 100 and transfer electrical signals to the second and third semiconductor chips 200 and 300, are disposed by a small pitch, space for a passive element may be insufficient.

However, in example embodiments, a passive element may be disposed at an edge portion of the first semiconductor chip 100, that is, a portion of the first semiconductor chip 100 that does not overlap (in the vertical direction) with the second and third semiconductor chips 200 and 300 stacked on the first semiconductor chip 100, and the first through electrode structures 120 for transferring electrical signals to the second and third semiconductor chips 200 and 300 are not disposed at the non-overlapping portion so that sufficient space for the passive elements may be provided.

Accordingly, the semiconductor package may include passive elements without an increase in size or otherwise without requiring additional space for the passive elements, and thus the electrical characteristics of the semiconductor package may be enhanced.

The passive elements may be electrically connected to the first through electrode structure 120 by the redistribution wiring structure 880 and the via structure 870 on the first semiconductor chip 100.

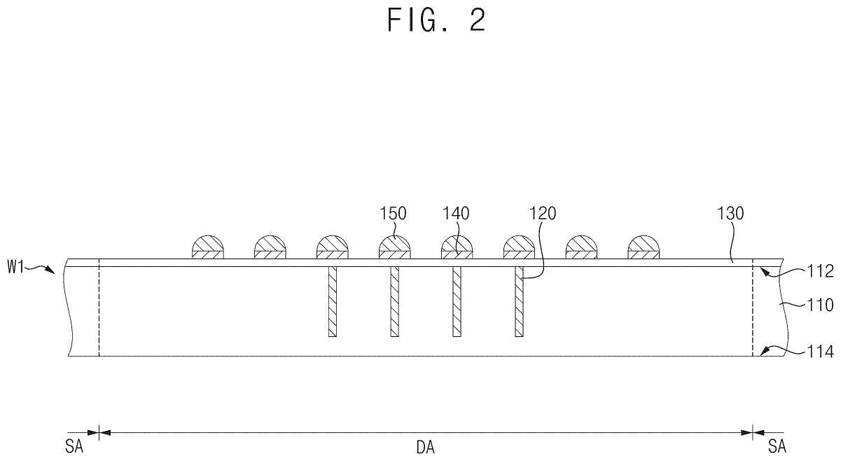

FIGS. 2 to 11 are cross-sectional views illustrating a method of manufacturing a semiconductor package in accordance with example embodiments.

Referring to FIG. 2, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may contain a first wiring structure therein. The first wiring structure may include, e.g., wirings, vias, contact plugs, etc.

A first conductive pad 140 may be formed on second insulating interlayer 130 to contact the first wiring structure to be electrically connected thereto. In example embodiments, a plurality of first conductive pads 140 may be spaced apart from each other in the horizontal direction.

In an example embodiment, the first conductive pad 140 may be formed by following processes.

A first seed layer may be formed on the second insulating interlayer 130, a first photoresist pattern including a first opening partially exposing an upper surface of the first seed layer may be formed on the first seed layer, and an electroplating process or an electroless plating process may be performed to form a first conductive pattern in the first opening.

The first photoresist pattern may be removed by, e.g., an ashing process and/or a stripping process to expose a portion of the first seed layer, the exposed portion of the first seed layer may be removed to form a first seed pattern.

Thus, a first conductive pad 140 including the first seed pattern and the first conductive pattern sequentially stacked in the vertical direction may be formed.

A first conductive connection member 150 may be formed on the first conductive pad 140.

In an example embodiment, the first conductive connection member 150 may be formed by following processes.

A second photoresist pattern including a second opening exposing an upper surface of the first conductive pad 140 may be formed on the second insulating interlayer 130, and an electroplating process or an electroless plating process may be performed to form a preliminary first conductive connection member in the second opening. After removing the second photoresist pattern, a reflow process may be performed so that the preliminary first conductive connection member may be transformed into a first conductive connection member 150.

In example embodiments, the first conductive connection member 150 may have a shape of, e.g., a semi-circle or a semi-ellipse.

In example embodiments, a first through electrode structure 120 extending in the vertical direction through an upper portion of the first substrate 110, that is, a portion of the first substrate 110 adjacent to the first surface 112 thereof may be formed. In example embodiments, a plurality of first through electrode structures 120 may be spaced apart from each other in the horizontal direction.

In an example embodiment, the first through electrode structure 120 may include a first through electrode extending in the vertical direction, a first barrier pattern covering a sidewall and a lower surface of the first through electrode, and a first insulation pattern covering a sidewall and a lower surface of the first barrier pattern.

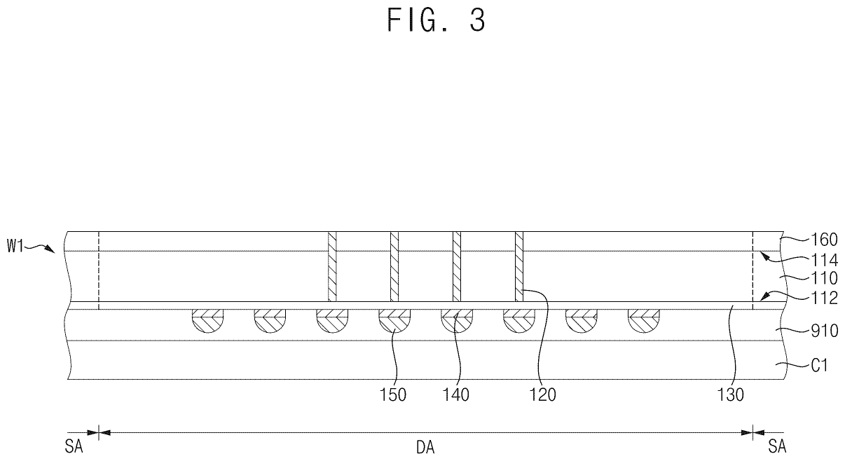

Referring to FIG. 3, a first temporary adhesion layer 910 may be attached to a first carrier substrate C1, and the first temporary adhesion layer 910 may be bonded with an upper surface of the second insulating interlayer 130 including the first wiring structure to cover the first conductive connection member 150 and the first conductive pad 140 on the first wafer W1 so that the first carrier substrate C1 may be bonded with the first wafer W1.

The first temporary adhesion layer 910 may include a material that is configured to lose adhesion by or responsive to irradiation of light, e.g., UV light or heat. In an example embodiment, the first temporary adhesion layer 910 may include glue.

After flipping the first wafer W1, a portion of the first substrate 110 adjacent to the second surface 114 of the first substrate 110 may be removed by, e.g., a grinding process to expose an upper portion of the first through electrode structure 120.

A first protective layer structure may be formed on the second surface 114 of the first substrate 110 to cover the first through electrode structure 120, and a planarization process may be performed on the first protective layer structure until an upper surface of the first through electrode of the first through electrode structure 120 is exposed to form a first protective pattern structure 160.

In example embodiments, the planarization process may include a chemical mechanical polishing (CMP) process and/or an etch back process.

In example embodiments, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns sequentially stacked in the vertical direction. An upper outer sidewall of a portion of the first protective pattern adjacent to the first through electrode structure 120 may be covered by the second protective pattern.

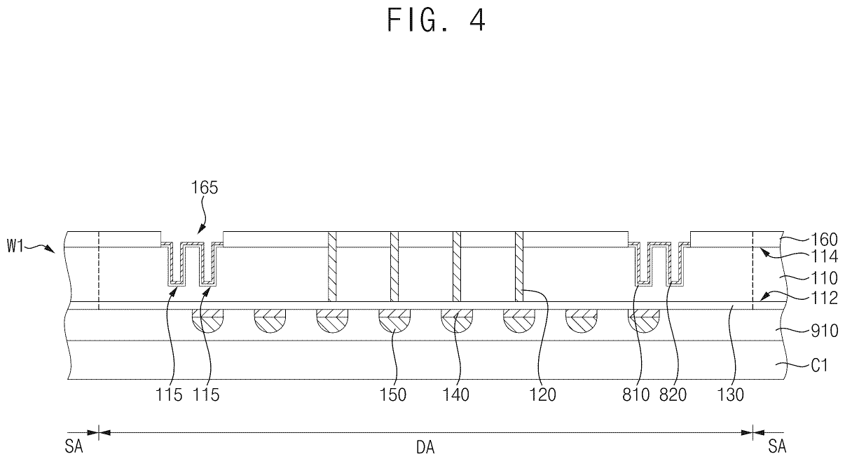

Referring to FIG. 4, the first protective pattern structure 160 may be partially removed by an etching process to form a third opening 165 partially exposing the second surface 114 of the first wafer W1, and an upper portion of the first wafer W1 exposed by the third opening 165 may be removed to form a trench 115.

In example embodiments, the third opening 165 and the trench 115 may be formed at a portion of the die region DA adjacent to the scribe lane region SA of the first wafer W1.

A pad layer and a lower electrode layer may be conformally stacked on inner walls of the trench 115 and the third opening 165, an upper surface of the first protective pattern structure 160 and an upper surface of the first through electrode structure 120, and may be patterned to form a pad 810 and a lower electrode 820, respectively. In example embodiments, the pad 810 and the lower electrode 820 may be formed on the inner wall of the trench 115 and a bottom of the third opening 165.

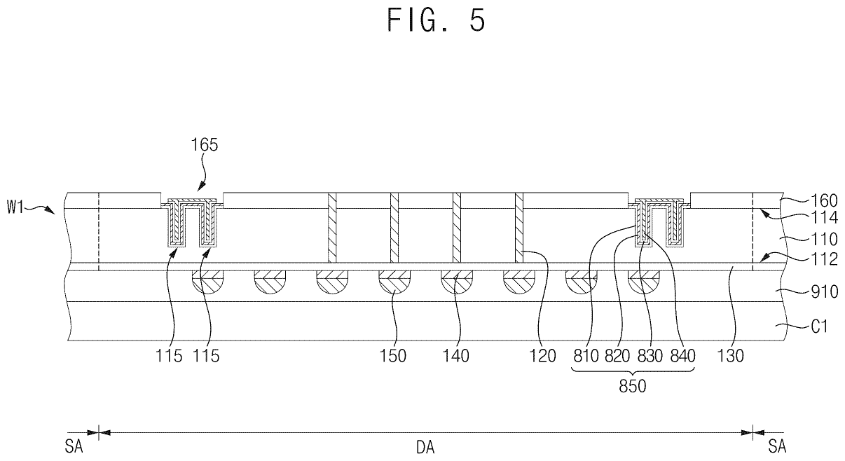

Referring to FIG. 5, a dielectric layer may be conformally formed on an upper surface of the lower electrode 820, the upper surface of the first through electrode structure 120 and the upper surface and a sidewall of the first protective pattern structure 160, an upper electrode layer may be formed on the dielectric layer to fill the trench 115, and the upper electrode layer and the dielectric layer may be patterned to form an upper electrode 840 and a dielectric pattern 830, respectively.

In example embodiments, the upper electrode 840 and the dielectric pattern 830 may be formed in the trench 115 and the third opening 165, and may partially expose a portion of the upper surface of the lower electrode 820.

The lower electrode 820, the dielectric pattern 830 and the upper electrode 840 sequentially stacked may collectively form a capacitor 850.

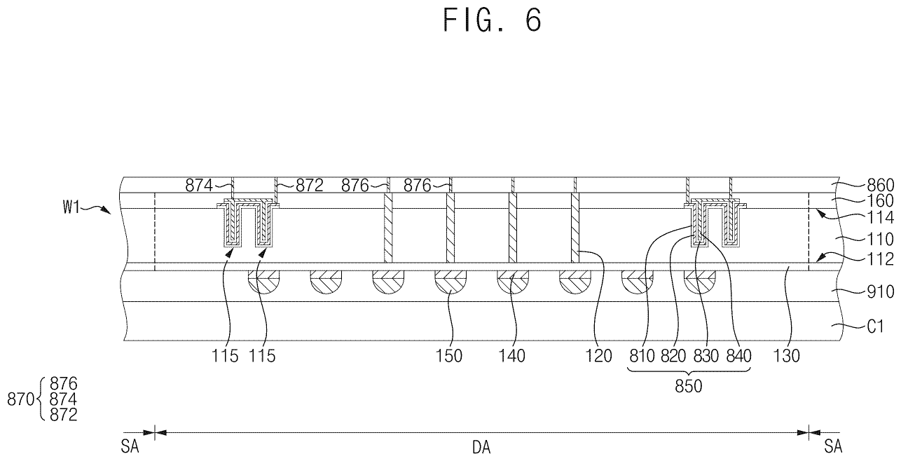

Referring to FIG. 6, a filling layer may be formed on the capacitor 850, the first through electrode structure 120 and the first protective pattern structure 160 to fill the third opening 165, and a planarization process may be performed on the filling layer until the upper surface of the first through electrode structure 120 is exposed to form a filling pattern in the third opening 165.

In example embodiments, the filling pattern may include a material substantially the same as that of the first protective pattern structure 160, particularly, the second protective pattern, and thus may be merged with the second protective pattern.

A first RDL 860 may be formed on the first protective pattern structure 160 and the first through electrode structure 120, and may be partially removed to form fourth to sixth openings exposing upper surfaces of the capacitor 850 and the first through electrode structure 120.

Particularly, the fourth opening may expose an upper surface of the lower electrode 820 of the capacitor 850, the fifth opening may expose an upper surface of the upper electrode 840 of the capacitor 850, and the sixth opening may expose an upper surface of the first through electrode structure 120.

A via layer may be formed on the first RDL 860 to fill the fourth to sixth openings, and a planarization process may be performed on the via layer until an upper surface of the via layer is exposed to form first to third vias 872, 874 and 876 in the fourth to sixth openings, respectively, which may collectively form a via structure 870.

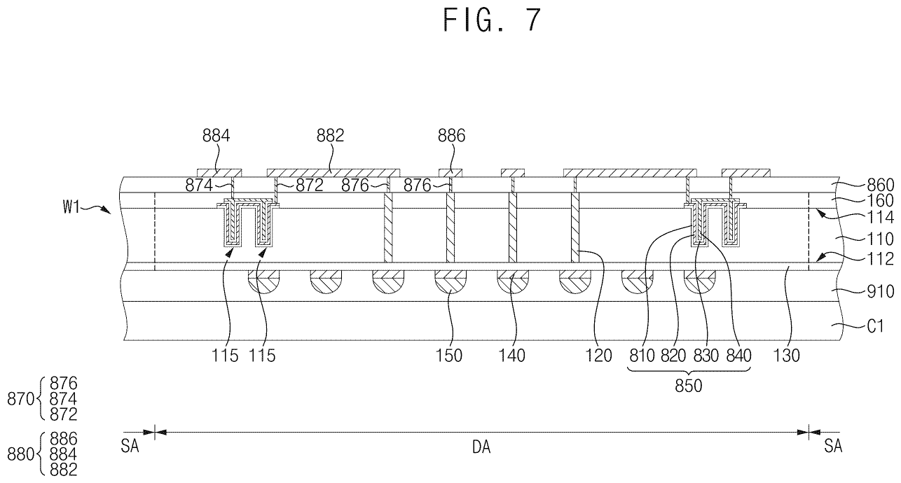

Referring to FIG. 7, a redistribution wiring structure layer may be formed on the first RDL 860, and may be patterned to form a redistribution wiring structure 880.

In example embodiments, the redistribution wiring structure 880 may include first to third wirings 882, 884 and 886. The first redistribution wiring 882 may commonly contact upper surfaces of the first and third vias 872 and 876, the first redistribution wiring 884 may contact an upper surface of the second via 874, and the third redistribution wiring 886 may contact an upper surface of the third via 876.

A portion of each of the first and second redistribution wirings 882 and 884 included in the redistribution wiring structure 880 may serve as a second conductive pad.

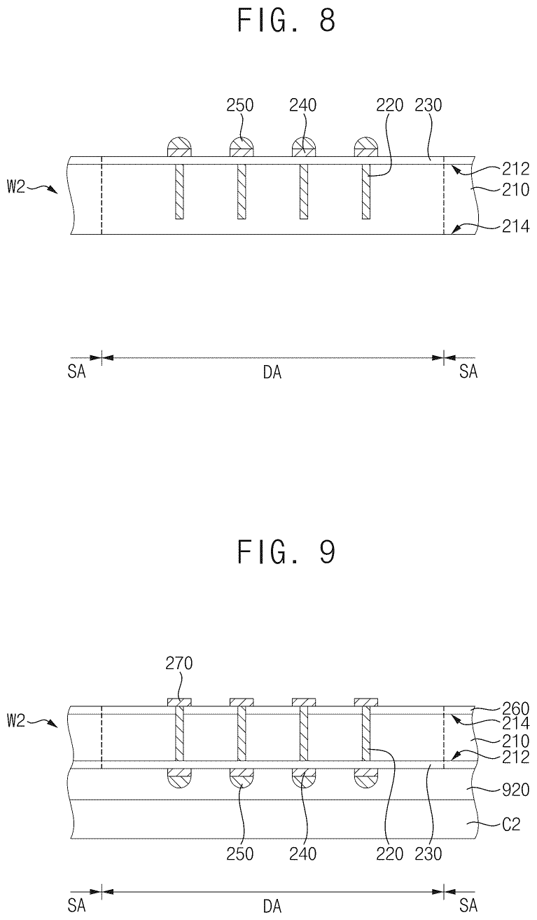

Referring to FIG. 8, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process to be singulated into a plurality of second semiconductor chips.

In the die region DA, a circuit device may be formed on the first surface 212 of the second substrate 210. The circuit device may include a memory device. The circuit device may include circuit patterns, and a third insulating interlayer may be formed on the first surface 212 of the second substrate 210 to cover the circuit patterns.

A fourth insulating interlayer 230 may be formed on the third insulating interlayer, and may contain a second wiring structure therein. The second wiring structure may include, e.g., wirings, vias, contact plugs, etc.

A third conductive pad 240 may be formed on fourth insulating interlayer 230 to contact the second wiring structure to be electrically connected thereto. In example embodiments, a plurality of third conductive pads 240 may be spaced apart from each other in the horizontal direction.

In an example embodiment, the third conductive pad 240 may be formed by processes substantially the same as or similar to those of the first conductive pad 140. Thus, the third conductive pad 240 may be formed to include a second seed pattern and a second conductive pattern sequentially stacked in the vertical direction.

A second conductive connection member 250 may be formed on the third conductive pad 240. In an example embodiment, the second conductive connection member 250 may be formed by processes substantially the same as or similar to those of the first conductive connection member 150. Thus, the second conductive connection member 250 may have a shape of, e.g., a semi-circle or a semi-ellipse.

In example embodiments, a second through electrode structure 220 extending through the second substrate 210 in the vertical direction may be formed. In example embodiments, a plurality of second through electrode structures 220 may be spaced apart from each other in the horizontal direction.

In an example embodiment, the second through electrode structure 220 may include a second through electrode extending in the vertical direction, a second barrier pattern covering a sidewall and a lower surface of the second through electrode, and a second insulation pattern covering a sidewall and a lower surface of the second barrier pattern.

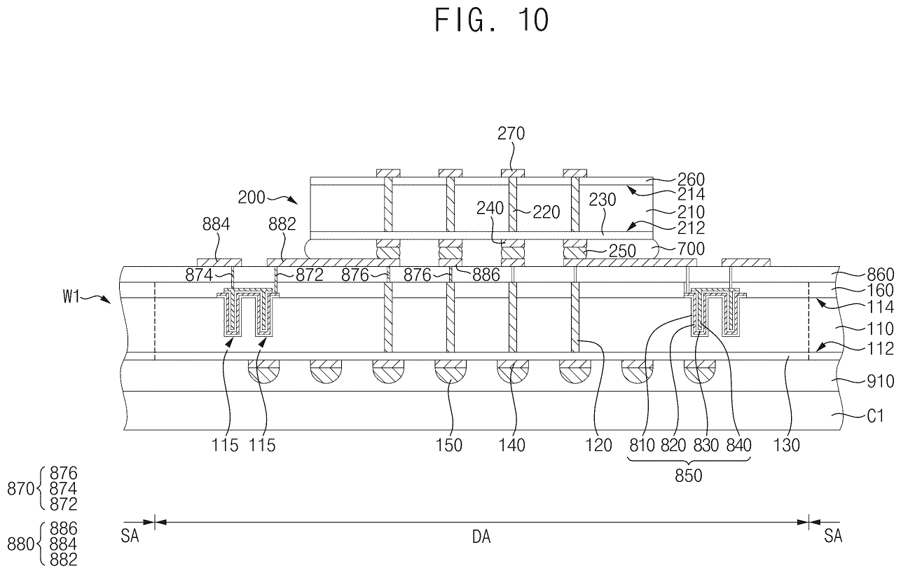

Referring to FIG. 9, processes substantially the same as or similar to those illustrated with respect to FIG. 3 may be performed.

Particularly, a second temporary adhesion layer 920 may be attached to a second carrier substrate C2, and the second temporary adhesion layer 920 may be bonded with an upper surface of the fourth insulating interlayer 230 including the second wiring structure to cover the second conductive connection member 250 and the third conductive pad 240 on the second wafer W2 so that the second carrier substrate C2 may be bonded with the second wafer W2. The second temporary adhesion layer 920 may include a material that is configured to lose adhesion by or responsive to irradiation of light, e.g., UV light or heat. In an example embodiment, the second temporary adhesion layer 920 may include glue.

After flipping the second wafer W2, a portion of the second substrate 210 adjacent to the second surface 214 of the second substrate 210 may be removed by, e.g., a grinding process to expose an upper portion of the second through electrode structure 220. A second protective layer structure may be formed on the second surface 214 of the second substrate 210 to cover the second through electrode structure 220, and a planarization process may be performed on the second protective layer structure until an upper surface of the second through electrode of the second through electrode structure 220 is exposed to form a second protective pattern structure 260. In example embodiments, the second protective pattern structure 260 may include third and fourth protective patterns sequentially stacked in the vertical direction.

A fourth conductive pad 270 may be formed on the second protective pattern structure 260 and the second through electrode structure 220. The fourth conductive pad 270 may include a third seed pattern and a third conductive pattern sequentially stacked in the vertical direction.

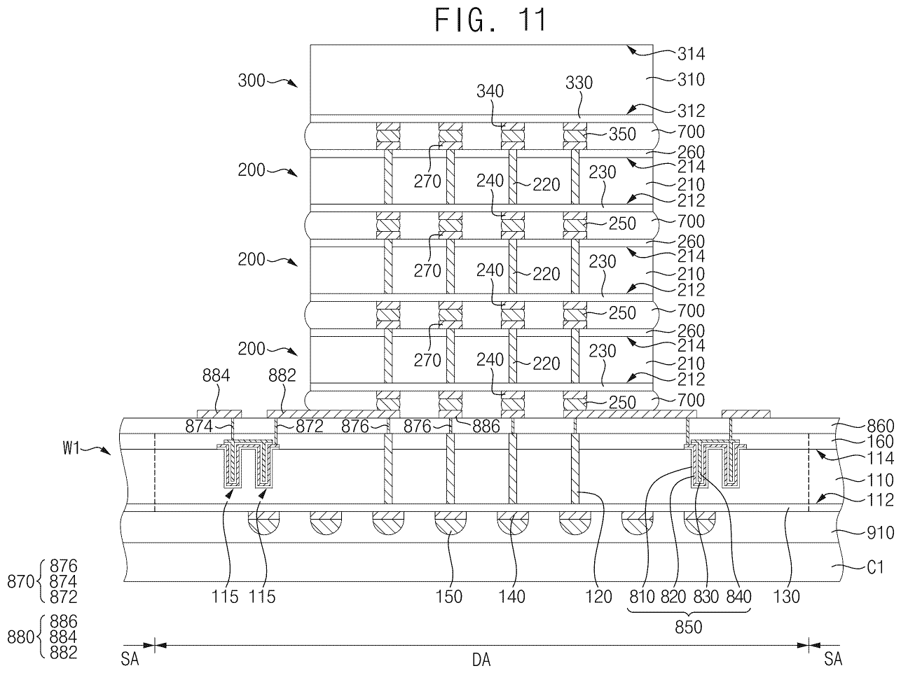

Referring to FIG. 10, after flipping the second wafer W2, the second wafer W2 may be attached to an upper surface of a release tape on a frame having a shape of, e.g., a ring.

The release tape may contact upper surfaces of the fourth conductive pad 270 and the second filling pattern structure 260 on the second surface 214 of the second wafer W2.

The second temporary adhesion layer 920 attached to the second carrier substrate C2 may be separated from the second conductive connection member 250, the third conductive pad 240 and the fourth insulating interlayer 230 so that the second carrier substrate C2 may be separated from the second wafer W2.

After cutting the second wafer W2 along the scribe lane region SA by a sawing process into second semiconductor chips 200, an adhesion layer 700 may be formed on the fourth insulating interlayer 230 of each of the second semiconductor chips 200.

The adhesion layer 700 may be formed on the fourth insulating interlayer 230 to cover the third conductive pad 240 and the second conductive connection member 250. The adhesion layer 700 may include a NCF, e.g., thermosetting resin.

In some embodiments, the adhesion layer 700 may be formed on the fourth insulating interlayer 230 of the second wafer W2, before the sawing process.

Each of the second semiconductor chips 200 may be separated from the release tape, and the adhesion layer 700 on each of the second semiconductor chips 200 may be attached to upper surfaces of the redistribution wiring structure 880 and the first RDL 860 so that each of the second semiconductor chips 200 may be mounted onto the first wafer W1. The second semiconductor chips 200 may be disposed on the respective die regions DA of the first wafer W1, and the second conductive connection member 250 of the second semiconductor chip 200 may contact the upper surface of the second conductive pad of the redistribution wiring structure 880.

In example embodiments, each of the second semiconductor chips 200 may not overlap the capacitor 850 on the first wafer W1.

A thermal compression bonding (TCB) process may be performed at a temperature equal to or less than about 400° C. so that the second semiconductor chips 200 may be bonded to the first wafer W1.

During the thermal compression process, the NCF included in the adhesion layer 700 may be melted to have fluidity, may flow into a space between each of the second semiconductor chips 200 and the first wafer W1 to cover sidewalls of the second conductive pad, the second conductive connection member 250 and the third conductive pad 240, and may be cured.

Referring to FIG. 11, a plurality of additional second semiconductor chips 200 may be stacked on the second semiconductor chip 200, and a third semiconductor chip 300 may be stacked on an uppermost one of the second semiconductor chips 200.

The third semiconductor chip 300 may be stacked on the uppermost one of the second semiconductor chips 200 by following processes.

Particularly, a third wafer may be provided. In example embodiments, the third wafer may include a third substrate 310 having first and second surfaces 312 and 314 opposite to each other in the vertical direction. Additionally, the third wafer may include a plurality of die regions and a scribe lane region surrounding each of the die regions. The third wafer may be cut along the scribe lane region by a sawing process to be singulated into a plurality of third semiconductor chips.

In the die region, a circuit device may be formed on the first surface 312 of the third substrate 310. The circuit device may include a memory device. The circuit device may include circuit patterns, and a fifth insulating interlayer may be formed on the first surface 312 of the third substrate 310 to cover the circuit patterns.

A sixth insulating interlayer 330 may be formed on the fifth insulating interlayer, and may contain a third wiring structure therein. The third wiring structure may include, e.g., wirings, vias, contact plugs, etc.

A fifth conductive pad 340 may be formed on sixth insulating interlayer 330 to contact the third wiring structure to be electrically connected thereto. In example embodiments, a plurality of fifth conductive pads 340 may be spaced apart from each other in the horizontal direction.

In an example embodiment, the fifth conductive pad 340 may be formed by processes substantially the same as or similar to those of the third conductive pad 240. Thus, the fifth conductive pad 340 may be formed to include a fourth seed pattern and a fourth conductive pattern sequentially stacked in the vertical direction.

A third conductive connection member 350 may be formed on the fifth conductive pad 340. In an example embodiment, the third conductive connection member 350 may be formed by processes substantially the same as or similar to those of the second conductive connection member 250. Thus, the third conductive connection member 350 may have a shape of, e.g., a semi-circle or a semi-ellipse.

A third temporary adhesion layer may be attached to a third carrier substrate, and the third temporary adhesion layer may be bonded with an upper surface of the sixth insulating interlayer 330 including the third wiring structure to cover the third conductive connection member 350 and the fifth conductive pad 340 on the third wafer so that the third carrier substrate may be bonded with the third wafer. The third temporary adhesion layer may include a material that is configured to lose adhesion by or responsive to irradiation of light, e.g., UV light or heat. In an example embodiment, the third temporary adhesion layer may include glue.

After flipping the third wafer, the third wafer may be attached to an upper surface of a release tape on a frame having a shape of, e.g., a ring. The third temporary adhesion layer attached to the third carrier substrate may be separated from the third conductive connection member 350, the fifth conductive pad 340 and the sixth insulating interlayer 330 so that the third carrier substrate may be separated from the third wafer.

After cutting the third wafer along the scribe lane region by a sawing process into third semiconductor chips 300, the adhesion layer 700 may be formed on the sixth insulating interlayer 330 of each of the third semiconductor chips 300. The adhesion layer 700 may cover the fifth conductive pad 340 and the third conductive connection member 350.

In some embodiments, the adhesion layer 700 may be formed on the sixth insulating interlayer 330 of the third wafer, before the sawing process.

Each of the third semiconductor chips 300 may be separated from the release tape, and the adhesion layer 700 on each of the third semiconductor chips 300 may be attached to upper surfaces of the fourth conductive pad 270 and the second protective pattern structure 260 of the second semiconductor chip 200 so that each of the third semiconductor chips 300 may be mounted onto the second semiconductor chip 200. The third conductive connection member 350 of the third semiconductor chip 300 may contact the upper surface of the fourth conductive pad 270 of the second semiconductor chip 200.

In example embodiments, each of the third semiconductor chips 300 may not overlap the capacitor 850 on the first wafer W1.

A TCB process may be performed so that each of the third semiconductor chips 200 may be bonded to the second semiconductor chip 200.

Referring to FIG. 1 again, a molding member 600 may be formed on the first wafer W1 to fill a space between structures each of which may include the second and third semiconductor chips 200 and 300.

In example embodiments, the molding member 600 may expose an upper surface of the third semiconductor chip 300.

The first wafer W1 may be cut along the scribe lane region SA by, e.g., a sawing process to be singulated into a plurality of first semiconductor chips 100.

During the sawing process, the molding member 600 may also be cut to cover sidewalls of the second and third semiconductor chips 200 and 300 on each of the first semiconductor chips 100.

The first temporary adhesion layer 910 and the first carrier substrate C1 may be separated from each of the first semiconductor chips 100 to complete manufacturing the semiconductor package.

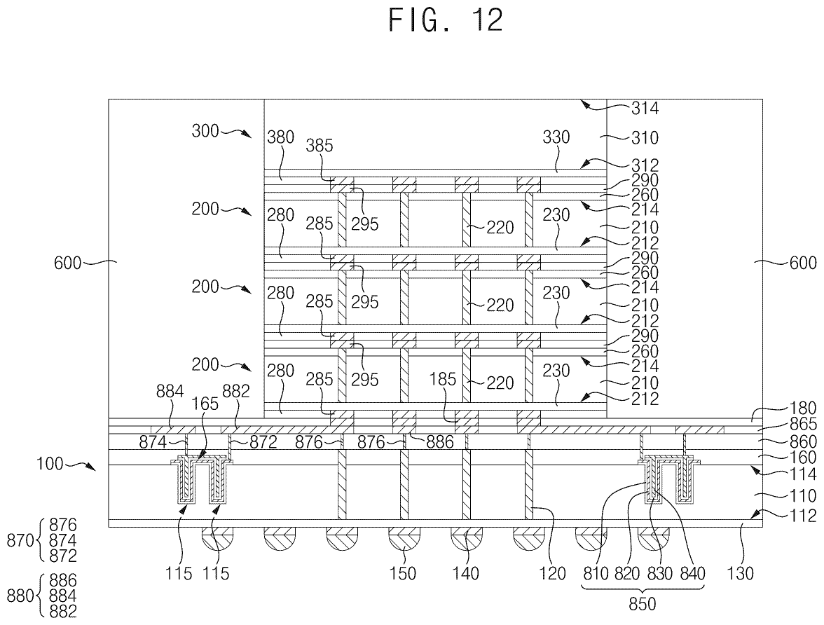

FIG. 12 is a cross-sectional view illustrating a semiconductor package in accordance with example embodiments. This semiconductor package may be substantially the same as or similar to that of FIG. 1 except for some elements, and thus repeated explanations of common or similar elements are omitted herein.

Referring to FIG. 12, the first to third semiconductor chips 100, 200 and 300 may be bonded with each other not by a TCB process but by a hybrid copper bonding (HCB) process.

Particularly, the first and second semiconductor chips 100 and 200 may be bonded with each other by an HCB process. Thus, a second RDL 865 covering a sidewall of the redistribution wiring structure 880 may be formed on the first RDL 860, and a first bonding layer 180 containing a first bonding pattern 185 therein may be formed on the redistribution wiring structure 880 and the second RDL 865. Additionally, a second bonding layer 280 containing a second bonding pattern 285 therein may be formed beneath the fourth insulating interlayer 230 of the second semiconductor chip 200, instead of the third conductive pad 240 and the second conductive connection member 250. Thus, the first and second bonding layers 180 and 280 may be bonded with each other to form a first bonding layer structure, and the first and second bonding patterns 185 and 285 may be bonded with each other to form a first bonding pattern structure.

Additionally, the second semiconductor chips 200 may be bonded with each other by an HCB process. Thus, a third bonding layer 290 containing a third bonding pattern 295 therein may be formed on the second protective pattern structure 260 and the second through electrode structure 220 of the second semiconductor chip 200, instead of the fourth conductive pad 270. The third bonding layer 290 of one of the second semiconductor chips 200 disposed at a lower level may be bonded with the second bonding layer 280 of one of the second semiconductor chips 200 disposed at an upper level to form a second bonding layer structure, and the second and third bonding patterns 285 and 295 may form a second bonding pattern structure.

Furthermore, the second and third semiconductor chips 200 and 300 may be bonded with each other by an HCB process. Thus, a fourth bonding layer 380 containing a fourth bonding pattern 385 therein may be formed beneath the sixth insulating interlayer 330 of the third semiconductor chip 300, instead of the fifth conductive pad 340 and the third conductive connection member 350. The fourth bonding layer 380 of the third semiconductor chip 300 may be bonded with the third bonding layer 290 of the second semiconductor chip 200 to form a third bonding layer structure, and the third and fourth bonding patterns 295 and 385 may be bonded with each other to form a third bonding pattern structure.

However, in some embodiments, some of the first and second semiconductor chips 100 and 200, the semiconductor chips 200, and the second and third semiconductor chips 200 and 300 may be bonded with each other by a TCB process, and others may be bonded with each other by an HCB process.

In example embodiments, each of the first to fourth bonding layers 180, 280, 290 and 380 may include, e.g., silicon carbonitride, silicon oxide, and each of the first to fourth bonding patterns 185, 285, 295 and 385 may include a metal, e.g., copper.

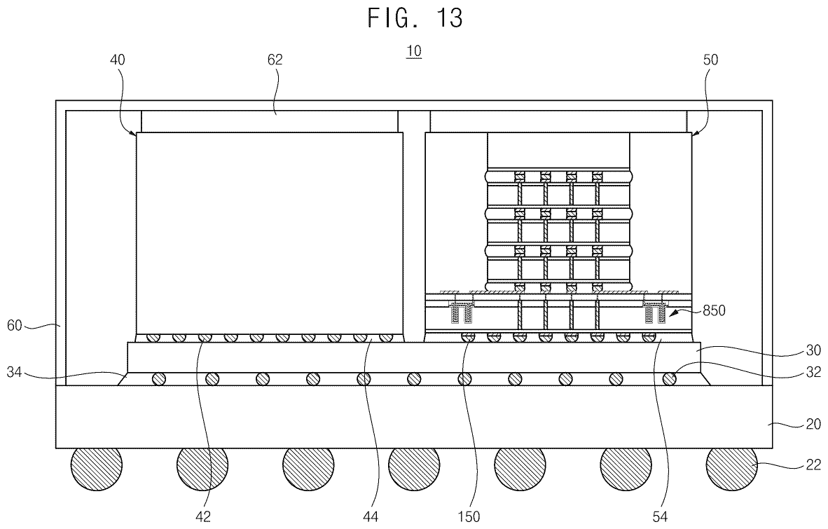

FIG. 13 is a cross-sectional view illustrating an electronic device in accordance with example embodiments.

This electronic device may include the semiconductor package shown in FIG. 1 as a second semiconductor device 50, however, the inventive concept may not be limited thereto, and for example, the semiconductor package shown in FIG. 12 may also serve as the second semiconductor device 50.

Referring to FIG. 13, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments, the electronic device 10 may be a memory module having a 2.5D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may include a semiconductor package, e.g., the HBM package of FIG. 1.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a fifth conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the fifth conductive connection member 32. The fifth conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a sixth conductive connection member 42. For example, the sixth conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are illustrated on the interposer 30, the inventive concept may not be limited thereto, and a plurality of first semiconductor devices 40 and/or a plurality of second semiconductor devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

The semiconductor device 50 may include a buffer die and a plurality of memory dies sequentially stacked on the buffer die. The buffer die and the memory dies may be electrically connected to each other by through electrodes, e.g., TSVs, and the through electrodes may be electrically connected to each other by conductive connection members. Data signals and control signals may be transferred to the buffer die and the memory dies by the through electrodes.

In example embodiments, the heat slug 60 be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a fourth conductive connection member 22 may be disposed beneath the conductive pad. In example embodiments, a plurality of fourth conductive connection members 22 may be spaced apart from each other in the horizontal direction. The fourth conductive connection member 22 may be, e.g., a solder ball. The electronic device 10 may be mounted on a module board via the fourth conductive connection members 22 to form a memory module.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a logic chip comprising a first substrate and a passive element on a portion of the first substrate;
a redistribution wiring structure on the logic chip, the redistribution wiring structure being electrically connected to the passive element;
memory chips sequentially stacked on the redistribution wiring structure in a vertical direction; and
a molding member on the logic chip, the molding member extending on sidewalls of the redistribution wiring structure and the memory chips,
wherein the passive element does not overlap the memory chips in the vertical direction.

2. The semiconductor package according to claim 1, wherein the first substrate includes first and second surfaces opposite to each other in the vertical direction, and the redistribution wiring structure is on the second surface of the first substrate, and
wherein the passive element is in a trench that is adjacent to the second surface of the first substrate.

3. The semiconductor package according to claim 2, wherein the passive element includes a capacitor that is electrically connected to the memory chips by the redistribution wiring structure.

4. The semiconductor package according to claim 3, wherein the logic chip comprises:
a first through electrode structure extending through the first substrate, the first through electrode structure including a first protrusion portion protruding beyond the second surface of the first substrate; and
a first protective pattern structure on the second surface of the first substrate, the first protective pattern structure extending on a sidewall of the first protrusion portion of the first through electrode structure, and
wherein the redistribution wiring structure is on the first protective pattern structure and the first through electrode structure and is electrically connected to the first through electrode structure.

5. The semiconductor package according to claim 4, wherein a lower portion of the capacitor is disposed in the trench, and an upper portion of the capacitor is covered by the first protective pattern structure.

6. The semiconductor package according to claim 5, wherein the capacitor comprises:
a lower electrode;
a dielectric pattern on the lower electrode; and
an upper electrode on the dielectric pattern, and
wherein at least one of the lower electrode or the upper electrode is electrically connected to the first through electrode structure by the redistribution wiring structure.

7. The semiconductor package according to claim 6, further comprising:
a redistribution layer (RDL) between the redistribution wiring structure and the first protective pattern structure, and between the redistribution wiring structure and the first through electrode structure;
a first via extending through the RDL and the first protective pattern structure and contacting the lower electrode;
a second via extending through the RDL and the first protective pattern structure and contacting the upper electrode; and
a third via extending through the RDL and contacting the first through electrode structure,
wherein the lower electrode is electrically connected to the first through electrode structure by the first via, the redistribution wiring structure, and the third via.

8. The semiconductor package according to claim 1, further comprising:
adhesion layers between respective ones of the memory chips that are sequentially stacked, and between the redistribution wiring structure and a lowermost one of the memory chips,
wherein the molding member extends on sidewalls of the adhesion layers.

9. The semiconductor package according to claim 1, wherein each of the memory chips comprises:
a second substrate including first and second surfaces opposite to each other in the vertical direction;
a second through electrode structure extending through the second substrate, the second through electrode structure including a second protrusion portion protruding beyond the second surface of the second substrate; and
a second protective pattern structure on the second surface of the second substrate, the second protective pattern structure extending on a sidewall of the second protrusion portion of the second through electrode structure.

10. The semiconductor package according to claim 9, wherein each of the memory chips comprises:
a first conductive pad and a conductive connection member sequentially stacked beneath the first surface of the second substrate in the vertical direction; and
a second conductive pad contacting an upper surface of the second through electrode structure, and
wherein the conductive connection member of a first one of the memory chips is bonded with the second conductive pad of a second one of the memory chips that is between the first one of the memory chips and the first substrate.

11. The semiconductor package according to claim 9, wherein each of the memory chips comprises:
a first bonding layer beneath the first surface of the second substrate, the first bonding layer including a first bonding pattern therein; and
a second bonding layer on the second protective pattern structure and the second through electrode structure, the second bonding layer including a second bonding pattern therein, and
wherein the first bonding layer of a first one of the memory chips is bonded with the second bonding layer of a second one of the memory chips that is between the first one of the memory chips and the first substrate, and the first and second bonding patterns contact each other.

12. A semiconductor package comprising:
a logic die comprising:
a substrate including first and second surfaces opposite to each other in a vertical direction;
a through electrode structure extending through the substrate, the through electrode structure comprising a protrusion portion protruding beyond the second surface of the substrate;
a protective pattern structure on the second surface of the substrate, the protective pattern structure extending on a sidewall of the protrusion portion of the through electrode structure; and
a capacitor comprising a lower portion and an upper portion, the lower portion of the capacitor extending into a portion of the substrate adjacent to the second surface thereof, and the upper portion of the capacitor having the protective pattern structure thereon;
a redistribution wiring structure on the logic die, the redistribution wiring structure being electrically connected to the capacitor;
memory dies sequentially stacked on the redistribution wiring structure; and
a molding member on the logic die, the molding member extending on sidewalls of the redistribution wiring structure and the memory dies,
wherein each of the memory dies does not overlap the capacitor in the vertical direction.

13. The semiconductor package according to claim 12, wherein the capacitor comprises:
a lower electrode;
a dielectric pattern on the lower electrode; and
an upper electrode on the dielectric pattern, and
wherein at least one of the lower electrode or the upper electrode is electrically connected to the through electrode structure by the redistribution wiring structure.

14. The semiconductor package according to claim 13, further comprising:
a redistribution layer (RDL) between the redistribution wiring structure and the protective pattern structure, and between the redistribution wiring structure and the through electrode structure;
a first via extending through the RDL and the protective pattern structure and contacting the lower electrode;
a second via extending through the RDL and the protective pattern structure and contacting the upper electrode; and
a third via extending through the RDL and contacting the through electrode structure,
wherein the lower electrode is electrically connected to the through electrode structure by the first via, the redistribution wiring structure, and the third via.

15. The semiconductor package according to claim 14, further comprising:
adhesion layers between respective ones of the memory dies that are sequentially stacked, and between the redistribution wiring structure and a lowermost one of the memory dies,
wherein the molding member extends on sidewalls of the adhesion layers.

16. A semiconductor package comprising:
a buffer die comprising:
a first substrate including first and second surfaces opposite to each other in a vertical direction;
a logic device in the first substrate;
a first wiring structure electrically connected to the logic device;
a first through electrode structure extending through the first substrate in the vertical direction, the first through electrode structure including a first protrusion portion protruding beyond the second surface of the first substrate;
a first protective pattern structure on the second surface of the first substrate, the first protective pattern structure extending on a sidewall of the first protrusion portion of the first through electrode structure; and
a capacitor comprising a lower portion and an upper portion, the lower portion of the capacitor extending into a portion of the first substrate adjacent to the second surface thereof, and the upper portion of the capacitor having the first protective pattern structure thereon;
a redistribution wiring structure on the buffer die, the redistribution wiring structure being electrically connected to the capacitor;
core dies sequentially stacked on the redistribution wiring structure in the vertical direction;
adhesion layers between the redistribution wiring structure and a lowermost one of the core dies, and between respective ones of the core dies that are sequentially stacked; and
a molding member on the buffer die, the molding member extending on sidewalls of the redistribution wiring structure, the core dies, and the adhesion layers,
wherein the capacitor does not overlap the core dies in the vertical direction.

17. The semiconductor package according to claim 16, wherein the capacitor comprises:
a lower electrode;
a dielectric pattern on the lower electrode; and
an upper electrode on the dielectric pattern, and
wherein at least one of the lower electrode or the upper electrode is electrically connected to the first through electrode structure by the redistribution wiring structure.

18. The semiconductor package according to claim 17, further comprising:
a redistribution layer (RDL) between the redistribution wiring structure and the first protective pattern structure, and between the redistribution wiring structure and the first through electrode structure;
a first via extending through the RDL and the first protective pattern structure and contacting the lower electrode;
a second via extending through the RDL and the first protective pattern structure and contacting the upper electrode; and
a third via extending through the RDL and contacting the first through electrode structure,
wherein the lower electrode is electrically connected to the first through electrode structure by the first via, the redistribution wiring structure, and the third via.

19. The semiconductor package according to claim 17, wherein each of the core dies comprises:
a second substrate including first and second surfaces opposite to each other in the vertical direction;
a memory device in the second substrate;
a second wiring structure electrically connected to the memory device;
a second through electrode structure extending through the second substrate, the second through electrode structure including a second protrusion portion protruding beyond the second surface of the second substrate; and
a second protective pattern structure on the second surface of the second substrate, the second protective pattern structure extending on a sidewall of the second protrusion portion of the second through electrode structure.

20. The semiconductor package according to claim 19, wherein each of the core dies comprises:
a first conductive pad and a conductive connection member sequentially stacked beneath the second wiring structure in the vertical direction; and
a second conductive pad contacting an upper surface of the second through electrode structure,
wherein the conductive connection member of a first one of the core dies is bonded with the second conductive pad of a second one of the core dies that is between the first one of the core dies and the first substrate, and
wherein sidewalls of the first and second conductive pads and the conductive connection member is covered by a respective adhesion layer of the adhesion layers.
